(19) United States
(12) Patent Application Publication
(10) Pub. No.: US 2025/0126901 A1
(43) Pub. Date: Apr. 17, 2025

(54) METHOD FOR REPAIRING A SOLAR PANEL AND SOLAR PANEL

(71) Applicant: HANWHA Q CELLS GMBH, Bitterfeld-Wolfen (DE)

(72) Inventors: Thoralf HARDER, Bitterfeld-Wolfen (DE); Alexander GRIMM, Bitterfeld-Wolfen (DE); Alexander HUSSACK, Bitterfeld-Wolfen (DE); Marc DEWENTER, Bitterfeld-Wolfen (DE); Michael QUINQUE, Bitterfeld-Wolfen (DE); Andreas BECKER, Bitterfeld-Wolfen (DE); Britta POHL-HAMPEL, Bitterfeld-Wolfen (DE); Maximilian SCHURADE, Bitterfeld-Wolfen (DE); Thomas GÖTTERMANN, Bitterfeld-Wolfen (DE)

(21) Appl. No.: 18/999,346

(22) Filed: Dec. 23, 2024

Related U.S. Application Data
(62) Division of application No. 16/759,349, filed on Apr. 26, 2020, now abandoned.

(30) Foreign Application Priority Data
Oct. 27, 2017 (DE) 102017125226.6

(51) Int. Cl. H10F 19/80; H10F 19/85; H10F 71/00

(52) U.S. Cl. CPC H10F 19/804; H10F 19/85; H10F 71/00

(57) ABSTRACT

A method for repairing a solar panel with a front-side-encapsulating element and a rear-side-encapsulating element, said method comprising the following steps: a) applying an adhesive paste or liquid to the rear-side-encapsulating element; b) applying a covering layer to the adhesive paste or liquid, and c) hardening the adhesive paste or liquid. The invention also relates to a solar panel comprising a front-side-encapsulating element, a rear-side-encapsulating element, an adhesive layer on a side of the rear-side-encapsulating element facing away from the front-side-encapsulating element, and a covering layer on a side of the adhesive layer facing away from the front-side-encapsulating element.

### RELATED APPLICATIONS

The present application is a Divisional of U.S. patent application Ser. No. 16/759,349, filed Apr. 26, 2020, which is a National Phase entry of PCT Application No. PCT/DE2018/100877, filed Oct. 26, 2018, which claims priority to German Patent Application No. 10 2017 125 226.6, filed Oct. 27, 2017, the disclosures of which are hereby incorporated by reference herein in their entireties.

### FIELD OF THE INVENTION

The invention relates to a method for repairing a solar panel having a front-side encapsulating element and a rear-side encapsulating element.

### BACKGROUND OF THE INVENTION

Solar panels are mounted outdoors the whole year round and so are subject to weathering and environmental effects such as UV radiation, temperature, damp, hail, snow, and wind. Rear-side encapsulating elements in particular may over their operating life, under exposure to the weathering effects, break down and/or show fault sites. Electrically conducting parts may be exposed. In that case they no longer meet the requirements of what is known as protection class II. The insulation faults can lead to a loss of performance of a solar panel system composed of a plurality of solar panel strings, since test mechanisms shut down solar panels with solar panel strings that are faulty in this way. If the solar panel is damaged, moreover, it is easy for moisture to penetrate the interior of the solar panel. This causes more rapid aging of the solar panel, which is likewise accompanied by a reduction in performance.

### SUMMARY

It is an object of the invention to provide a solar panel and a method for repairing a solar panel that result in prevention of electrical insulation faults.

This object is achieved in accordance with the invention by a method having the features as claimed.

The invention relates to a method for repairing a solar panel having a front-side encapsulating element and a rear-side encapsulating element, comprising the following steps:

a) applying an adhesive paste or liquid to the rear-side encapsulating element,

b) applying a covering layer to the adhesive paste or liquid,

c) curing the adhesive paste or liquid.

The method eliminates and/or prevents electrical insulation faults in the solar panel. The method can be carried out at a location at which the solar panel is mounted. The solar panel need not be transported, but can instead be repaired in its operating environment or directly adjacent thereto, so making the method cost-effective. The method, moreover, is uncomplicated. A plug disposed on the rear-side encapsulating element may be, but does not have to be, removed from the rear-side encapsulating module for the method to be carried out.

The method is suitable particularly for a solar panel whose rear-side encapsulating element has been damaged over some or all of its area.

Steps a) and b) are carried out in the order specified. That is, after the application of the adhesive paste or liquid to the rear-side encapsulating element as per step a), step b) is carried out, in which the covering layer is applied to the adhesive paste or liquid. A curing reaction of the adhesive paste or liquid may begin even during the implementation of step a), but step b) is carried out before the completion of the curing, i.e., of step c). That is, step b) is carried out when the adhesive paste or liquid is as yet not fully cured, although the curing of the adhesive paste or liquid may have already been triggered. The curing of the adhesive paste or liquid as per step c) may therefore have been triggered even before step b), but the curing is not completed during step b), instead being completed only in step c).

The adhesive paste or liquid is cured as per step c). The expression “curing” means a solidification by means, for example, of crosslinking of the adhesive paste or liquid, which is executed inactively or passively and/or actively by the operative of the method. For example, the adhesive paste or liquid crosslinks by reaction with atmospheric moisture which is present anyway, or the adhesive sets physically, and so the operative of the method does not actively trigger the solidification. Alternatively, the curing is triggered, for example, by crosslinking of the adhesive paste or liquid as a result of active addition or mixing of a component or sub-component to a further component of the adhesive paste or liquid before and/or during step a) by the operative of the method. For the implementation of step c), preferably a predetermined time is allowed to elapse. In other words, a wait is observed until the adhesive paste or liquid has cured.

By means of the method, an insulating bonded-assembly layer is applied to the damaged solar panel, in the form of the cured adhesive paste or liquid in conjunction with a mechanically protecting and insulating layer in the form of the covering layer, to give a cost-optimized, reliable solar panel with extended lifetime. The solar panel need not be replaced after damage, but can instead be reliably repaired by means of the method. Consequently, the solar panel can continue to be used as a source of energy. Moreover, the lifetime of the solar panel is extended by the application of an additional insulating layer, especially since less moisture is able to penetrate into the interior of the solar panel. As a result, a moisture-induced aging with attendant reduction in performance is decelerated. Furthermore, the method can be employed both individually in the case of one damaged solar panel in a solar panel system comprising a plurality of solar panels, and also in the case of a plurality of damaged solar panels in the solar panel system, making the method scalable ad infinitum.

The solar panel is preferably cleaned of soiling before step a). The soiling may be removed, for example, using one or more brooms, brushes, sponges, suction cleaners with and/or without use of cleaning liquids. As a result, adhesion between the rear-side encapsulating element and the layers applied in steps a) to c) can be improved, and defects arising from inclusion of dirt particles can be avoided.

The expression “applying” in step a) preferably comprises spraying, knifecoating, spreading and/or squirting of the adhesive paste or liquid onto the rear-side encapsulating element. Step a) can be carried out in one step or in two or more steps. Preferably step a) is carried out in one step.

Step b) is carried out preferably using a covering layer which is self-adherent on the adhesive.

The adhesive paste or liquid is preferably selected from the group of the physically setting or chemically curing adhesives. A physically setting adhesive is understood to be an adhesive for which the fully formed adhesive itself, in other words the polymer per se, is applied to the rear-side encapsulating element. In this case a physical method is employed, which brings the adhesive first into a processible form, i.e., into adhesive paste or adhesive liquid form, before curing of the adhesive in step c), i.e., the leaving of the adhesive to solidify further; a curing reaction may as described above begin as early as in step a) and/or b). A chemically curing adhesive, also called reactive adhesive, is understood to be an adhesive for which the curing and/or solidification is achieved through chemical reaction of one or more components of the adhesive.

In one preferred embodiment the adhesive paste or liquid is selected from the group consisting of methyl methacrylate, silicone, MS polymer (silane-modified polymer), polysulfide, polyurethane adhesive paste or liquid. More preferably, a silicone paste or liquid is selected as adhesive paste or liquid.

The silicone paste or liquid is preferably a one-component RTV silicone system of the alkoxy-, oxime- and/or acetoxy-curing type and step c) is initiated by atmospheric moisture. The expression “RTV silicone” stands for room temperature-vulcanizing silicone. The RTV silicone crosslinks preferably at an ambient temperature between 23 and 30° C. and a relative atmospheric humidity in the range from 30 to 60%. RTV silicone of the alkoxy-, oxime- and/or acetoxy-curing type gives off small amounts of a byproduct on curing: alkanol such as methanol or ethanol, oximes or acetic acid, respectively. These silicones have good bond strength and, moreover, are relatively inexpensive. The RTV silicone is more preferably a one-component RTV silicone of the alkoxy-curing type. It has a comparatively good bond strength, is not corrosive, and does not release any unpleasant odor on curing. The one-component RTV silicone is applied preferably in the form of a nonfluid paste or spreadable liquid to the rear-side encapsulating element.

Alternatively, the silicone paste or liquid is preferably a two-component RTV silicone system of the alkoxy-curing type and step c) is initiated by prior mixing and reaction of the second component with the first component. This silicone as well is relatively inexpensive, has comparatively good bond strength, is not corrosive, and does not release any unpleasant odor on curing. The two-component RTV silicone is applied preferably in the form of a spreadable liquid to the rear-side encapsulating element.

In a further alternative, the silicone paste or liquid is a two-component silicone system with a noble metal crosslinking catalyst, and step c) is initiated by prior mixing and reaction of the second component with the first component.

In one preferred embodiment, step a) and step b) are carried out directly after one another. In other words, no further step is carried out between step a) and b). There is no need for application of an intermediate ply such as, for example, an adherent layer between the cured silicone and the covering layer.

Step a) and step b) are preferably carried out on the full area or substantially the full area of the rear-side encapsulating element. “Substantially the full area” refers to an area coverage of more than 80%, preferably more than 90%. As a result, it is possible to extend the lifetime of the solar panel, since less moisture is able to penetrate into the interior of the solar panel, and so moisture-induced aging with attendant reduction in performance is decelerated.

In one preferred embodiment the covering layer is a single-ply or multiply polymeric film. More preferably, the covering layer comprises a polyester layer, a polyamide layer, a polyolefin layer and/or a fluoropolymer layer. The covering layer preferably comprises PET (polyethylene terephthalate), PO (polyolefin) such as, for example, PE (polyethylene) or PP (polypropylene), PVF (polyvinyl fluoride), PVDF (polyvinylidene fluoride) and/or PA (polyamide).

In one preferred embodiment the covering layer comprises a fluoropolymer. The fluoropolymer is preferably polyvinyl fluoride. It is dirt-repellent, resistant to numerous chemicals, and impervious to fats and oils. Furthermore, it exhibits comparatively excellent weathering resistance. The covering layer is preferably an opaque film. The combination of polyvinyl fluoride material with the cured adhesive material, particularly in the case of silicone, is ideal in respect of time, costs, and reliability of the repair. This combination of materials is especially weathering-resistant and meets relatively exacting quality standards while at the same time being relatively inexpensive.

In one preferred embodiment the covering layer is a film assembly with a polyvinyl fluoride layer, the polyvinyl fluoride layer being disposed as an outer layer, i.e., on a side of the film assembly that faces away from the rear-side encapsulating element.

The covering layer preferably has a layer thickness in the range from 10 to 600 μm, more preferably 30 to 500 μm. These layer thicknesses are sufficient to ensure many years of effective weather resistance.

The solar panel used in the method comprises the front-side encapsulating element, the rear-side encapsulating element, and solar cells laminated in and disposed between these two elements. In one preferred embodiment the rear-side encapsulating element comprises a rear-side film or a rear-side film laminate to which the adhesive paste or liquid is applied as per step a), and the front-side encapsulating element is glass. The solar panel is therefore preferably a glass-film solar panel.

The front-side encapsulating element, the laminated-in solar cells, and the rear-side encapsulating element are preferably in the form of layers and form a layer stack in the form of a solar panel laminate module, which has side edges. The laminated-in solar cells are also referred to hereinafter as solar cell laminate layer. The solar panel preferably comprises a solar panel frame which surrounds the side edges of the solar panel and/or its layer stack or its solar panel laminate module, and engages around the front-side encapsulating element and the rear-side encapsulating element; the solar panel is subjected to steps a) to c) in the presence of the solar panel frame. The solar panel frame has, for example, four corner connectors and also four frame parts made of aluminum, for example, which are compressed with the corner connectors. The frame parts and corner connectors surround the side edges of the solar panel laminate module and continue to lie, in plan view, on the marginal regions of the front-side and rear-side encapsulating elements, respectively. The solar panel frame is not removed before the method is carried out; instead, it is disposed on the solar panel laminate module during the implementation of steps a) to c).

During the implementation of the method, the solar panel frame is present on the solar panel-that is, it is not removed before the method is carried out. This saves on method steps possibly leading to further damage to the solar panel. Especially if the front-side encapsulating element is a thermally prestressed glass, damage to the glass during removal of the solar panel frame can be avoided. If the solar panel frame has four corner connectors and also four frame parts compressed therewith, this solar panel frame can be removed only with plastic deformation, and hence its removal would require the mounting of a new solar panel frame onto the solar panel. The method of this invention saves on such requirements and is therefore cost-effective.

The invention further relates to a solar panel comprising a front-side encapsulating element, a rear-side encapsulating element, an adhesive layer on a side of the rear-side encapsulating element facing away from the front-side encapsulating element, and a covering layer on a side of the adhesive layer facing away from the front-side encapsulating element. Advantageous embodiments described in relation to the method are valid correspondingly for the solar panel, and vice versa.

The solar panel preferably has the following layer construction in the order stated: front-side encapsulating element/laminated-in solar cells/rear-side encapsulating element/adhesive layer/covering layer. In one preferred embodiment the covering layer lies directly on the adhesive layer, i.e., there is no intermediate layer such as an adherent layer, for example, disposed between them. The covering layer is disposed self-adherently on the adhesive layer. The adhesive layer is preferably a silicone layer. The covering layer is preferably a fluoropolymer, more preferably polyvinyl fluoride. In one preferred embodiment the front-side encapsulating element is glass, and the rear-side encapsulating element is a rear-side film or a rear-side film laminate. The solar panel preferably comprises a solar panel frame which surrounds the side edges of the solar panel and engages around the front-side encapsulating element and the rear-side encapsulating element, as described above.

In one preferred embodiment the adhesive layer is disposed on the full area or substantially the full area of the rear-side encapsulating element, and the covering layer is disposed on the full area or substantially the full area of the adhesive layer.

### BRIEF DESCRIPTION OF THE DRAWINGS

Further properties and advantages of the invention are shown in connection with the figures and described illustratively below. In the drawing, which is schematic and not to scale,

FIG. 1 shows a flow diagram of a method of the invention;

FIG. 2 shows a cross-sectional view of a solar panel of the invention in a first variant; and

FIG. 3 shows a cross-sectional view of a solar panel of the invention in a second variant.

### DETAILED DESCRIPTION

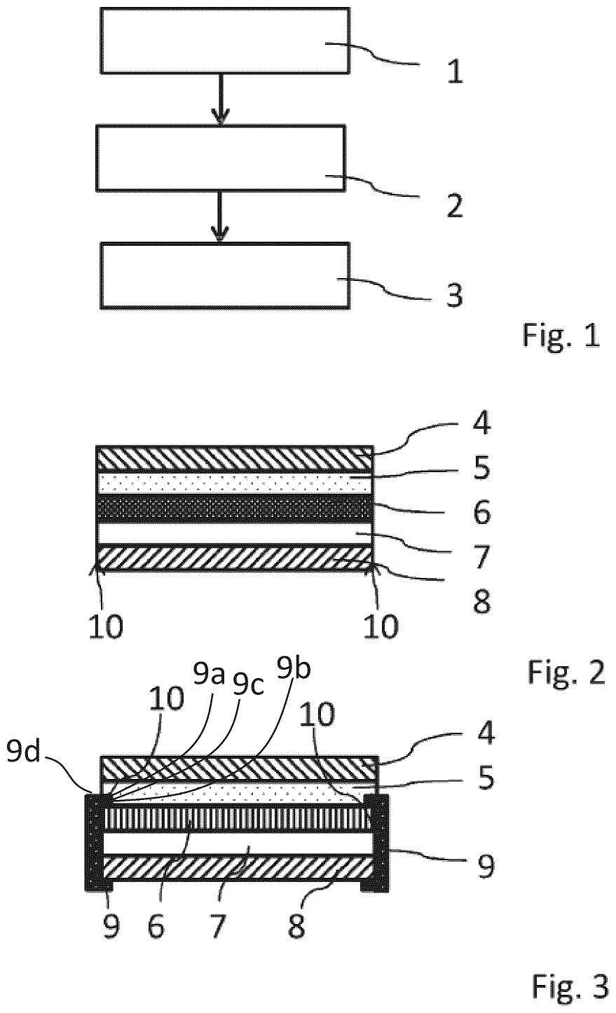

FIG. 1 shows a flow diagram of a method of the invention. In the method a solar panel is repaired which has a front-side encapsulating element and a rear-side encapsulating element. The method begins with step 1, in which, corresponding to step a), an adhesive paste or liquid in the form, for example, of a one-component or two-component RTV silicone is applied to the rear-side encapsulating element. Subsequently in a step 2, corresponding to step b), a covering layer is applied to the adhesive paste or liquid. Step 2 is followed by a step 3, in which the adhesive paste or liquid is cured in accordance with step c). If, for example, a one-component RTV silicone is employed in the method, it cures by reaction with atmospheric moisture water molecules from the environment at room temperature. If, for example, a two-component RTV silicone is employed in the method, the silicone paste or liquid begins to cure by mixing and reaction of the two components, the mixing being performed before step a). Step 3 envisages that a predetermined time is allowed to elapse for the adhesive paste or liquid to cure.

FIG. 2 shows, in a cross-sectional view which is purely schematic and is not to scale, a solar panel of the invention in a first variant. The solar panel comprises a front-side encapsulating element 8 and a rear-side encapsulating element 6, located between which is a solar cell laminate layer 7 which comprises laminated-in solar cells. On a side of the rear-side encapsulating element 6 facing away from the front-side encapsulating element 8 there is also an adhesive layer 5 over the full area. On a side of the adhesive layer 5 facing away from the front-side encapsulating element 8, there is also a covering layer 4 over the full area, in the form, for example, of a film assembly, which comprises a polyvinyl fluoride layer.

The front-side encapsulating element 8, the rear-side encapsulating element 6, and the solar cell laminate layer 7 form a solar panel laminate module which is formed from the above-described layer stack and has side edges 10, two of which are visible in FIG. 2. The solar panel comprising this solar panel laminate module, after damage to the rear-side encapsulating element 6, has been subjected to the method shown in FIG. 1, and so after the implementation of this method it additionally comprises the adhesive layer 5 and the covering layer 4.

FIG. 3 shows, in a cross-sectional view which is purely schematic and is not to scale, a solar panel of the invention in a second variant. The solar panel shown in FIG. 3 corresponds to the solar panel shown in FIG. 2-identical reference symbols have been used for identical structural elements, and the statements made are valid correspondingly. In contrast to the construction shown in FIG. 2, the solar panel shown here has a solar panel frame 9 which surrounds the side edges 10 and engages around the front-side encapsulating element 8 and the rear-side encapsulating element 6. Here, as well, the solar panel has been subjected to the method 10 depicted in FIG. 1, with the solar panel frame 9 having been disposed on the solar panel laminate module during the implementation of the method shown in FIG. 1. The method was carried out on the solar panel in the presence of the solar panel frame 9.

### LIST OF REFERENCE SYMBOLS

1 Step a)

2 Step b)

3 Step c)

4 Covering layer

5 Adhesive layer

6 Rear-side encapsulating element

7 Solar cell laminate layer

8 Front-side encapsulating element

9 Solar panel frame

10 Side edge

What is claimed:

1. A method for repairing a solar panel having a front-side encapsulating element and a rear-side encapsulating element, comprising the following steps:
a) applying an adhesive paste or liquid to the rear-side encapsulating element,
b) applying a covering layer to the adhesive paste or liquid applied in step a), and
c) curing the adhesive paste or liquid.

2. The method as claimed in claim 1, wherein the adhesive paste or liquid is selected from the group consisting of methyl methacrylate, silicone, MS polymer, polysulfide, polyurethane adhesive paste or liquid, the adhesive paste or liquid being a silicone paste or liquid.

3. The method as claimed in claim 2, wherein the silicone paste or liquid is a one-component RTV silicone system of the alkoxy-, oxime- and/or acetoxy-curing type and step b) is initiated by atmospheric moisture.

4. The method as claimed in claim 2, wherein the silicone paste or liquid is a two-component RTV silicone system of the alkoxy-curing type and step b) is initiated by mixing and reacting the second component with the first component, or wherein the silicone paste or liquid is a two-component silicone system with a noble metal crosslinking catalyst and step b) is initiated by mixing and reacting the second component with the first component.

5. The method as claimed in claim 1, wherein step a) and step b) are carried out directly after one another.

6. The method as claimed in claim 1, wherein a) and step b) are carried out on the full area or substantially the full area of the rear-side encapsulating element.

7. The method as claimed in claim 1, wherein the covering layer is a single-ply or multiply polymeric film comprising a polyester layer, a polyamide layer, a polyolefin layer and/or a fluoropolymer layer.

8. The method as claimed in claim 1, wherein the covering layer comprises a polyvinyl fluoride layer.

9. The method as claimed in claim 1, wherein the covering layer has a layer thickness in a range from 10 to 600 μm.

10. The method as claimed in claim 9, wherein the covering layer has a layer thickness in a range from 30 to 500 μm.

11. The method as claimed in claim 1, wherein the rear-side encapsulating element comprises a rear-side film or a rear-side film laminate, to which the adhesive paste or liquid is applied as per step a), and wherein the front-side encapsulating element is glass.

12. The method as claimed in claim 1, wherein the solar panel has a solar panel frame which surrounds side edges of the solar panel and engages around the front-side encapsulating element and the rear-side encapsulating element, and wherein the solar panel is subjected to steps a) to c) in the presence of the solar panel frame.
